(19) United States
(12) Patent Application Publication
(10) Pub. No.: US 2021/0280622 A1
(43) Pub. Date: Sep. 9, 2021

(54) SOLID-STATE IMAGING APPARATUS AND ELECTRONIC APPARATUS

(71) Applicant: SONY SEMICONDUCTOR SOLUTIONS CORPORATION, KANAGAWA (JP)

(72) Inventors: HIDENORI MAEDA, KANAGAWA (JP); TOSHIFUMI WAKANO, KANAGAWA (JP); YUSUKE OTAKE, KANAGAWA (JP)

(21) Appl. No.: 17/252,810

(22) PCT Filed: Jun. 7, 2019
(86) PCT No.: PCT/JP2019/022699

§ 371 Date: Dec. 16, 2020

(30) Foreign Application Priority Data
Jun. 25, 2018 (JP) 2018-119768

(51) Int. Cl. H01L 27/146; H01L 31/107

(52) U.S. Cl. CPC H01L 27/14623; H01L 31/107; H01L 27/1463; H01L 27/14627

(57) ABSTRACT

Providing a SPAD photodiode that accurately captures a subject regardless of long distance or short distance. A solid-state imaging apparatus (1000) according to the present disclosure includes: a pixel isolator (100) that defines a photoelectric conversion region (200) for each pixel; a first semiconductor layer (106) provided in the photoelectric conversion region; and a second semiconductor layer (108) to which a voltage for electron multiplication is applied, specifically between the first semiconductor layer and the second semiconductor layer, in which the sensitivities of the plurality of pixels are varied. With this configuration, it is possible to accurately capture a subject in the SPAD photodiode regardless of long distance or short distance.

### FIELD

The present disclosure relates to a solid-state imaging apparatus and an electronic apparatus.

### BACKGROUND

As a conventional art, Patent Literature 1 below describes a photoelectric conversion element in which the light receiving area of a first pixel and the light receiving area of a second pixel are varied.

### CITATION LIST

### Patent Literature

Patent Literature 1: Japanese Laid-open Patent Publication No. 2017-117834

### SUMMARY

### Technical Problem

Recently, there has been known a photodiode, referred to as a SPAD photodiode, in which a voltage for electron multiplication is applied between a first semiconductor layer and a second semiconductor layer provided in a photoelectric conversion region defined for each of pixels.

In the SPAD photodiode, when the amount of incident light is large, such as when imaging a high-luminance subject, the relationship of the received light signal with respect to the amount of light changes compared to when the light amount is small. In such a case, there arises a problem of a failure in performing distance measurement of the subject with high accuracy.

More specifically, there is a need to prepare a high-sensitivity SPAD photodiode in order to cover a long distance in widening the distant measurement range of the SPAD photodiode. However, when the amount of incident light is large in a high-sensitivity SPAD photodiode, the relationship between the received light signal and the amount of light changes compared to the case where the amount of light is small, leading to a situation of difficulty in performing distance measurement with high-illuminance light such as sunlight.

In the technique described in Patent Literature 1, the sensitivity is varied for each of pixels by varying the pixel size. Such a method would require a relatively large-scale structure change, that is, a change in the cell size of a pixel, and thus has a problem of time and labor taken for the design change and an increase in the manufacturing cost.

Therefore, there has been a demand for the SPAD photodiode to have a capability of capturing the subject with high accuracy regardless of long distance or short distance.

### Solution to Problem

In accordance with one aspect of the present disclosure, a solid-state imaging apparatus comprises a pixel isolator that defines a photoelectric conversion region for each pixel; a first semiconductor layer provided in the photoelectric conversion region; and a second semiconductor layer to which a voltage for electron multiplication is applied, specifically between the first semiconductor layer and the second semiconductor layer, wherein sensitivities of the photoelectric conversion regions of the plurality of pixels are varied.

### Advantageous Effects of Invention

According to the present disclosure, it is possible to capture a subject in a SPAD photodiode with high accuracy regardless of long distance or short distance.

It is noted that the above effects are not necessarily limited, and, along with or instead of the above effects, any of the effects described in the present specification or other effects which can be understood from the present specification may be exhibited.

### BRIEF DESCRIPTION OF DRAWINGS

FIG. 1 is a plan view illustrating a solid-state imaging element (SPAD photodiode) according to an embodiment of the present disclosure.

FIG. 2 is a schematic cross-sectional view illustrating a configuration of one pixel of a solid-state imaging element.

FIG. 3 is a plan view illustrating a solid-state imaging element, similarly to FIG. 1, illustrating an example including condenser lenses of several sizes.

FIG. 4 is a plan view illustrating an example of providing a pixel that does not include a condenser lens.

FIG. 5 is a plan view illustrating an example in which one pixel includes a plurality of condenser lenses.

FIG. 6 is a schematic view illustrating an example of performing sensitivity adjustment for each of pixels by varying the width of the light shielding film for each of the pixels.

FIG. 7 is a schematic view illustrating an example of performing sensitivity adjustment for each of pixels by varying the width of the light shielding film for each of the pixels.

FIG. 8 is a schematic cross-sectional view illustrating a configuration of light shielding films of three pixels.

FIG. 9 is a plan view illustrating a solid-state imaging element, illustrating an example in which three pixels out of four pixels are provided with a plurality of types of light shielding films having various light shielding widths.

FIG. 10 is a plan view illustrating variations of the shape of the opening of the light shielding film.

FIG. 11 is a schematic view illustrating an example in which transmissive films provided between a photoelectric converter and a condenser lens have various thicknesses.

FIG. 12 is a schematic cross-sectional view illustrating a detailed configuration of a photoelectric converter, in contrast to the configuration illustrated in FIG. 11.

FIG. 13 is a block diagram illustrating a configuration example of a camera device as an electronic apparatus to which the present technology is applied.

### DESCRIPTION OF EMBODIMENTS

Hereinafter, preferred embodiments of the present disclosure will be described in detail with reference to the accompanying drawings. In the present specification and the drawings, components having substantially the same functional configuration will be denoted with the same reference numerals and redundant description will be omitted.

Note that the description will be provided in the following order.

1. Example of configuration of solid-state imaging element according to the present embodiment
1.1. Basic configuration example of solid-state imaging element
1.2. Example of varying the size of the condenser lens for each of pixels
1.3. Example of varying the width of the light shielding film for each of pixels
1.4. Example of varying the thickness of the transmissive film between the photoelectric converter and the condenser lens

2. Application example of the solid-state imaging element according to the present embodiment

1. Example of Configuration of Solid-State Imaging Element According to the Present Embodiment

1.1. Basic Configuration Example of Solid-State Imaging element

There is a technology of the Single Photon Avalanche Diode (SPAD) that achieves a photodiode having a one-photon level readout sensitivity by performing electron multiplication. In order to induce multiplication, the SPAD uses a high voltage of approximately ±several tens of volts. The SPAD is a device capable of detecting one photon in each of pixels by multiplying carriers generated by photoelectric conversion in a high electric field PN junction region provided in each of pixels.

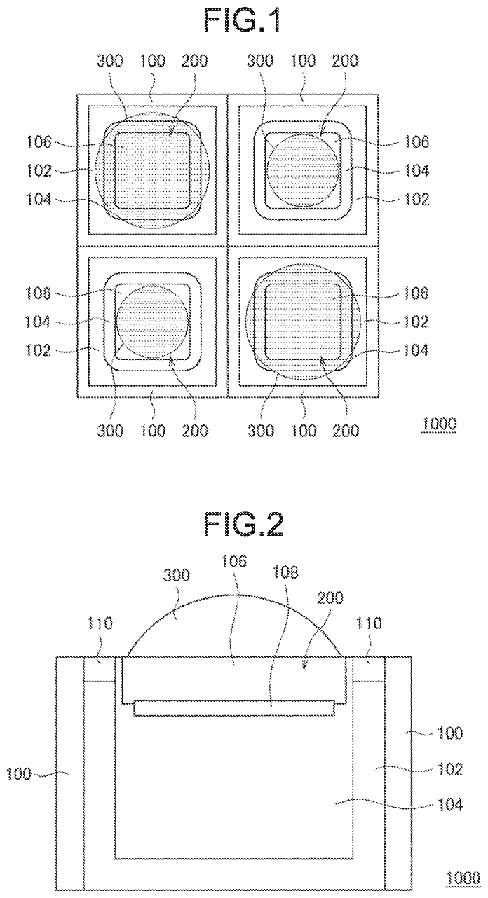

FIG. 1 is a plan view illustrating a solid-state imaging element (SPAD photodiode; as solid-state imaging apparatus) 1000 according to an embodiment of the present disclosure. FIG. 1 illustrates four pixels included in a solid-state imaging element 1000. FIG. 2 is a schematic cross-sectional view illustrating a configuration of one pixel of the solid-state imaging element 1000. In the present embodiment, the lower layer cell size is the same; however, the lens size and shape, and the light shielding width of the condensing portion in the upper layer are varied, and whereby the sensitivity is controlled only by changing the upper layer layout without changing the lower layer layout.

As illustrated in FIGS. 1 and 2, each of pixels of the solid-state imaging element 1000 is partitioned by an element isolator 100, and each of the pixels includes a photoelectric converter 200. The element isolator 100 is formed of an insulating film or a metal film, for example. As illustrated in FIG. 2, each of pixels partitioned by the element isolator 100 includes a P-type layer 102 extending from an edge of the element isolator 100 to the bottom of each of pixels, and the P-type layer 102 includes an N-type layer 104.

Furthermore, a high-concentration N-type layer 106 is provided on the light irradiation surface side (upper side in the drawing) of the photoelectric converter 200, and a high-concentration P-type layer 108 is provided below the high-concentration N-type layer 106 Furthermore, a high-concentration P-type layer 110 is provided on the P-type layer 102 formed along the element isolator 100. For example, a high voltage is applied between the P-type layer 108 and the N-type layer 104 to induce the electron multiplication described above. The conductivity types of the impurity layers are an example, and P and N may be replaced with each other to have opposite conductivity types. In addition, there are various other methods for forming the multiplication region having a high electric field. Furthermore, an impurity implantation region for isolating the multiplication region may be provided, or Sallow Trench Isolation (STI) or the like may be provided as the pixel isolator 150.

1.2. Example of Varying the Size of the Condenser Lens for Each of Pixels

Above the photoelectric converter 200, a condenser lens 300 that condenses light onto the photoelectric converter 200 is provided. As illustrated in FIG. 1, the condenser lens 300 is formed in a size varied for each of pixels.

In the example illustrated in FIG. 1, the condenser lenses 300 in the upper left pixel and the lower right pixel in the drawing are larger in size than the condenser lenses 300 in the lower left pixel and the upper right pixel. This makes it possible to vary the sensitivity for each of pixels at the time of performing photoelectric conversion in accordance with the size of the condenser lens 300. In the example illustrated in FIG. 1, the condenser lenses 300 of the upper left pixel and the lower right pixel have the same size, while the condenser lenses 300 of the lower left pixel and the upper right pixel have the same size.

In the example illustrated in FIG. 1, the position of the condenser lens 300 is arranged at the center of the pixel. However, the position of the condenser lens 300 may be shifted from the center of the pixel in accordance with the position of the pixel in a pixel region of an imaging surface. For example, in the pixel located in the upper right of the pixel region, the condenser lens 300 is arranged in the lower left with respect to the center of the pixel. This makes it possible to optimally set the position of the condenser lens 300 in accordance with the position of the pixel on the imaging surface.

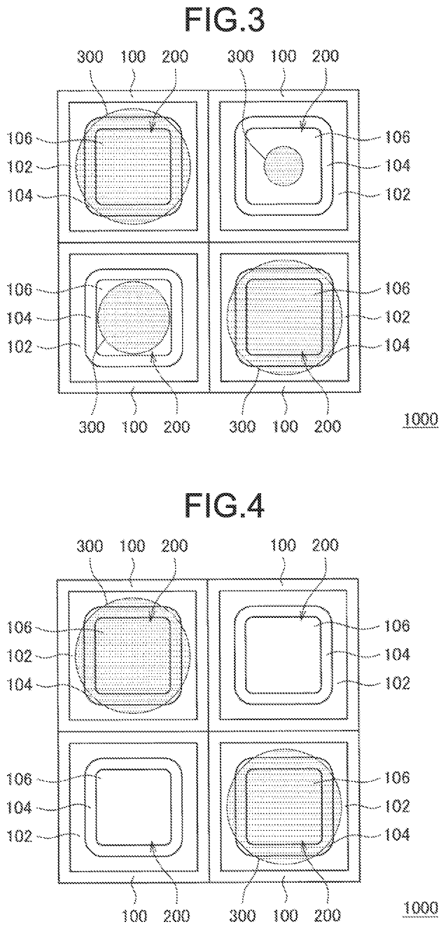

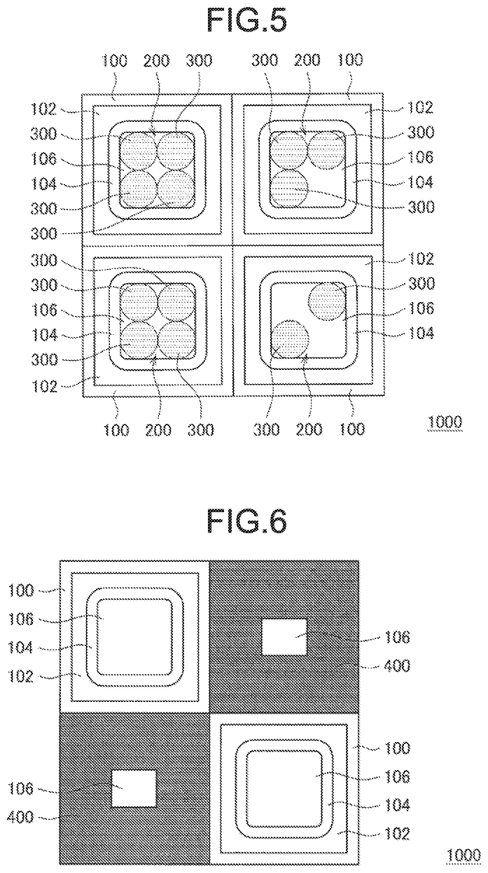

FIG. 3 is a plan view illustrating a solid-state imaging element 1000 similar to FIG. 1, illustrating an example including condenser lenses 300 of several sizes. FIG. 4 is a plan view illustrating an example of providing a pixel that does not include the condenser lens 300. FIG. 5 is a plan view illustrating an example in which one pixel includes a plurality of condenser lenses 300. In the examples of FIGS. 3 to 5, it is also possible to vary the sensitivity for each of pixels at the time of performing photoelectric conversion in accordance with the size of the condenser lens 300.

As illustrated in FIG. 4, providing a pixel without the condenser lens 300 makes it possible to achieve a wider sensitivity difference with respect to the pixel including the condenser lens 300. Furthermore, as illustrated in FIG. 5, providing a plurality of condenser lenses 300 for one pixel makes it possible to improve the condensing efficiency. In addition, adjusting the number of the plurality of condenser lenses 300 makes it possible to easily adjust the sensitivity. As described above, sensitivity adjustment can be performed for each of pixels also in the examples illustrated in FIGS. 3 to 5.

1.3. Example of Varying the Width of the Light Shielding Film for Each of Pixels

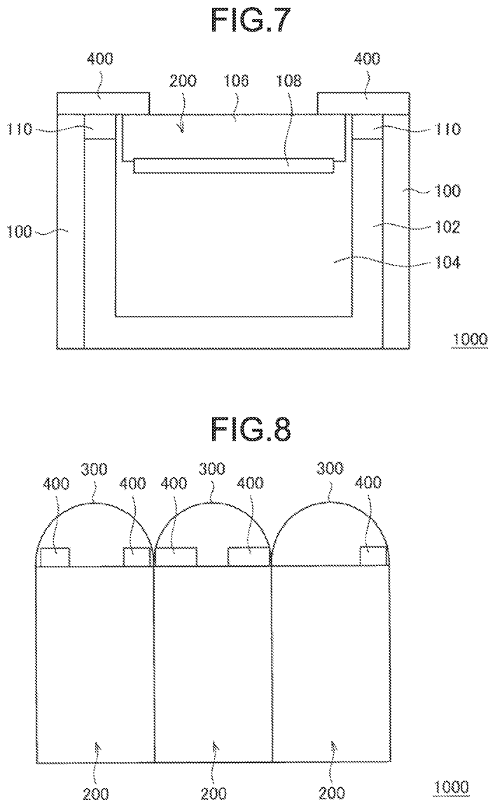

FIGS. 6 and 7 are schematic views illustrating an example of performing sensitivity adjustment for each of pixels by varying the width of the light shielding film for each of the pixels. FIG. 6 is a plan view illustrating the solid-state imaging element 1000 similarly to FIG. 1, illustrating four pixels included in the solid-state imaging element 1000.

In FIG. 6, the basic configuration of each of pixels including the photoelectric converter 200 is similar to the configurations in FIGS. 1 and 2. In FIG. 6, some pixels have light shielding films 400. FIG. 7 is a schematic cross-sectional view illustrating a configuration of a pixel having the light shielding film 400. The light shielding film 400 has a function of shielding part of the light incident on the photoelectric converter 200. In this manner, providing the light shielding film 400 on some pixels makes it possible to perform sensitivity adjustment for each of pixels. Note that, in FIG. 7, the condenser lens 300 may be provided on the light shielding film 400.

FIG. 8 is a schematic cross-sectional view illustrating a configuration of the light shielding films 400 of three pixels. As illustrated in FIG. 8, the condenser lens 300 is provided corresponding to the photoelectric converter 200 of each of pixels. Furthermore, the light shielding film 400 is provided on the photoelectric converter 200 of each of pixels. Although each of the pixels has the same cell size, the width of the region shielded by the light shielding film 400 is varied. This makes it possible to perform sensitivity adjustment for each of pixels.

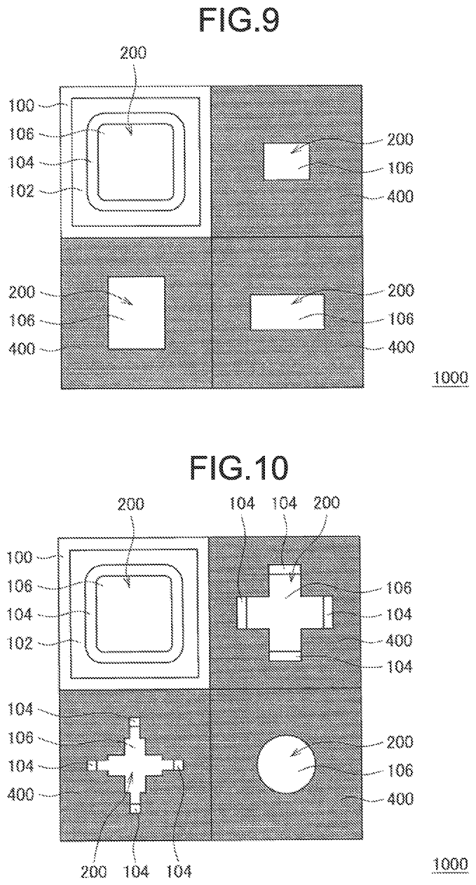

Similarly, FIG. 9 is a plan view illustrating the solid-state imaging element 1000, illustrating an example in which three pixels out of four pixels are provided with a plurality of types of the light shielding films 400 having various light shielding widths. This makes it possible to perform sensitivity adjustment for each of pixels.

FIG. 10 is a plan view illustrating variations of the shape of the opening of the light shielding film 400. In FIG. 10, the openings of the light shielding film 400 of the upper right and lower left pixels in the drawing have cross shapes. Furthermore, the shape of the opening of the light shielding film 400 of the lower right pixel is circular. The shape of the opening of the light shielding film 400 can be various shapes such as a rectangle, a polygon, and a circle.

1.4. Example of Varying the Thickness of the Transmissive Film Between the Photoelectric Converter and the Condenser Lens

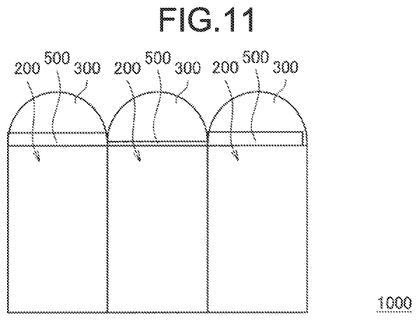

FIG. 11 is a schematic view illustrating an example in which transmissive films 500 provided between the photoelectric converter 200 and the condenser lens 300 have various thicknesses. The light emitted on the light irradiation surface of the photoelectric converter 200 is transmitted through the transmissive film 500 so as to be incident on the photoelectric converter 200. The transmissive film 500 is formed of an insulating film. The transmissive film 500 may be formed of a metal film.

FIG. 11 is a schematic cross-sectional view illustrating a configuration of the transmissive film 500 of three pixels. As illustrated in FIG. 11, the condenser lens 300 is each provided corresponding to the photoelectric converter 200 of each of pixels. In each of pixels, the transmissive film 500 is provided between the condenser lens 300 and the photoelectric converter 200.

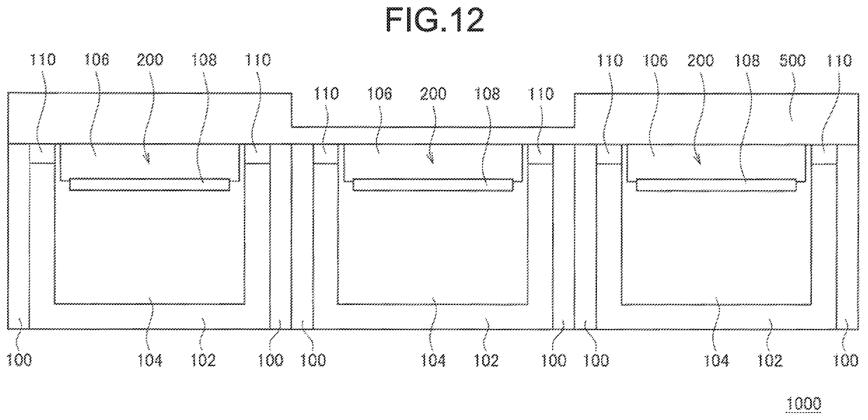

As illustrated in FIG. 11, the transmissive film 500 of the central pixel is formed to be thinner than the transmissive films 500 of the pixels on both sides thereof. FIG. 12 is a schematic cross-sectional view illustrating a detailed configuration of the photoelectric converter 200 of each of pixels, in contrast to the configuration illustrated in FIG. 11. The detailed configuration of the photoelectric converter 200 is similar to that illustrated in FIG. 2. Note that FIG. 12 omits illustration of the condenser lens 300. In this manner, varying the thickness of the transmissive film 500 for each of pixels makes it possible to perform sensitivity adjustment for each of pixels.

2. Application Example of the Solid-State Imaging Element According to the Present Embodiment

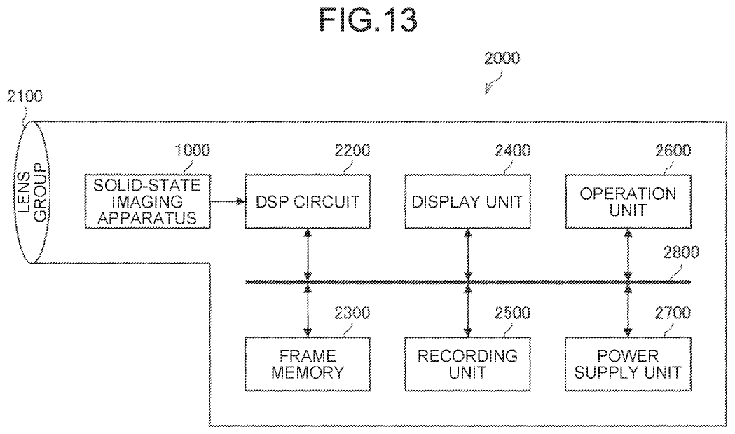

FIG. 13 is a block diagram illustrating a configuration example of a camera device 2000 as an electronic apparatus to which the present technology is applied. The camera device 2000 illustrated in FIG. 20 includes an optical unit 2100 including a lens group, the above-described solid-state imaging apparatus (imaging device) 1000, and a DSP circuit 2200 that is a camera signal processing device. The camera device 2000 further includes frame memory 2300, a display unit (display device) 2400, a recording unit 2500, an operation unit 2600, and a power supply unit 2700. The DSP circuit 2200, the frame memory 2300, the display unit 2400, the recording unit 2500, the operation unit 2600, and the power supply unit 2700 are connected to each other via a bus line 2800.

The optical unit 2100 captures incident light (image light) from a subject and forms an image on an imaging surface of the solid-state imaging apparatus 1000. The solid-state imaging apparatus 1000 converts the light amount of the incident light imaged by the optical unit 2100 on the imaging surface into a pixel-based electrical signal and outputs it as a pixel signal.

The display unit 2400 includes, for example, a panel type display device such as a liquid crystal panel or an organic Electro Luminescence (EL) panel, and displays a moving image or a still image captured by the solid-state imaging apparatus 1000. The DSP circuit 2200 receives the pixel signal output from the solid-state imaging apparatus 1000 and performs processing for displaying an image on the display unit 2400. The recording unit 2500 records a moving image or a still image captured by the solid-state imaging apparatus 1000 onto a recording medium such as a video tape or a Digital Versatile Disk (DVD).

The operation unit 2600 issues operation commands for various functions of the solid-state imaging apparatus 1000 based on user's operation. The power supply unit 2700 appropriately supplies various power, which are operation power supplies, to the DSP circuit 2200, the frame memory 2300, the display unit 2400, the recording unit 2500, and the operation unit 2600, as power supply targets.

As described above, according to the present embodiment, it is possible to achieve providing pixels having various sensitivities by merely changing the layout of the upper layer of the solid-state imaging apparatus 1000, leading to achievement of the solid-state imaging element 1000 having a wide dynamic range.

The preferred embodiments of the present disclosure have been described in detail above with reference to the accompanying drawings, but the technical scope of the present disclosure is not limited to such examples. It is obvious that a person having ordinary knowledge in the technical field of the present disclosure can come up with various changes or modifications within the scope of the technical idea described in the claims, and these are understood, of course, to belong to the technical scope of the present disclosure.

Furthermore, the effects described in the present specification are merely illustrative or exemplary and are not limited. That is, the technique according to the present disclosure can exhibit other effects that are apparent to those skilled in the art from the description of the present specification in addition to or instead of the above effects.

Note that the following configurations also belong to the technical scope of the present disclosure.

### REFERENCE SIGNS LIST

300 CONDENSER LENS
400 LIGHT SHIELDING FILM
500 TRANSMISSIVE FILM
1000 SOLID-STATE IMAGING ELEMENT

1. A solid-state imaging apparatus comprising:
a pixel isolator that defines a photoelectric conversion region for each pixel;
a first semiconductor layer provided in the photoelectric conversion region; and
a second semiconductor layer to which a voltage for electron multiplication is applied, specifically between the first semiconductor layer and the second semiconductor layer,
wherein sensitivities of the photoelectric conversion regions of the plurality of pixels are varied.

2. The solid-state imaging apparatus according to claim 1, further comprising a condenser lens provided for each of pixels on a light irradiation surface,
wherein the condenser lens has a size varied for each of pixels.

3. The solid-state imaging apparatus according to claim 2, further comprising the pixel that does not include the condenser lens.

4. The solid-state imaging apparatus according to claim 2, wherein a plurality of the condenser lenses is provided in one pixel.

5. The solid-state imaging apparatus according to claim 1, further comprising a light shielding portion that shields light reaching a light irradiation surface of the photoelectric conversion region for each of pixels,
wherein a light shielding width of the light shielding portion is varied for each of pixels.

6. The solid-state imaging apparatus according to claim 5, wherein a shape of an opening of the light shielding portion is a polygon or a circle.

7. The solid-state imaging apparatus according to claim 1, further comprising a transmissive film that is provided, for each of the pixels, on a light irradiation surface of the photoelectric conversion region and that is configured to transmit light reaching the light irradiation surface,
wherein the transmissive film provided for each of the pixels has a thickness varied for each of pixels.

8. An electronic apparatus comprising a solid-state imaging apparatus including: a pixel isolator that defines a photoelectric conversion region for each pixel; a first semiconductor layer provided in the photoelectric conversion region; and a second semiconductor layer to which a voltage for electron multiplication is applied, specifically between the first semiconductor layer and the second semiconductor layer, in which sensitivities of the photoelectric conversion regions of the plurality of pixels are varied.
